(19) United States
(12) Patent Application Publication
(10) Pub. No.: US 2026/0329537 A1
(43) Pub. Date: Oct. 22, 2026

(54) COMPUTER-IN-MEMORY (CIM) SYSTEM IMPLEMENTING SPARSITY FOR COMPUTATION ACCELERATION

(71) Applicant: TAIWAN SEMICONDUCTOR MANUFACTURING COMPANY, LTD., Hsinchu (TW)

(72) Inventors: Xiaochen PENG, San Jose, CA (US); Brian CRAFTON, San Jose, CA (US); Murat Kerem AKARVARDAR, Hsinchu (TW)

(73) Assignee: TAIWAN SEMICONDUCTOR MANUFACTURING COMPANY, LTD., Hsinchu (TW)

(21) Appl. No.: 19/349,604

(22) Filed: Oct. 3, 2025

Related U.S. Application Data
(60) Provisional application No. 63/789,711, filed on Apr. 16, 2025.

(51) Int. Cl. G06F 7/523; G06F 7/50

(52) U.S. Cl. CPC G06F 7/523; G06F 7/50

(57) ABSTRACT

This disclosure is directed to a memory device and a method of implementing multiply-and-accumulate (MAC) operations in the memory device based on an N:M sparsity scheme. The memory device includes a memory array with a first portion configured to store weights and a second portion configured to store indices associated with the weights. The memory device further includes a multiplexer circuit, a multiplier circuit, and an adder circuit. The multiplexer circuit is configured to receive data and the indices, and output a subset of the data based on the indices. The multiplier circuit is configured to multiply the subset of the data by corresponding weights to generate outputs. The adder circuit is configured to sum the outputs.

### CROSS-REFERENCE TO RELATED APPLICATIONS

The present application claims the benefit of U.S. Provisional Patent Appl. No. 63/789,711, filed on Apr. 16, 2025, which is incorporated herein by reference in its entirety.

### BACKGROUND

Memory devices, such as random-access memory (RAM), store data and transmit the data to external devices (such as a processor) for various computational operations. A memory device equipped with a compute-in-memory (CIM) system can not only store the data, but also perform calculations and data processing. With the CIM system and the related data processing methods, the stored data can be processed directly within the memory device rather than by external devices. Moreover, the data can be analyzed more efficiently within the memory device, which enables faster processing of application, such as artificial intelligence (AI) applications. machine learning applications, deep learning applications, convolutional neural networks (CNNs), large language model applications, and generative AI. These AI applications can involve extensive scales of multiplication and addition operations in multiply-accumulate (MAC) circuits in the CIM system.

### BRIEF DESCRIPTION OF THE DRAWINGS

Aspects of the present disclosure are best understood from the following detailed description when read with the accompanying figures. It is noted that, in accordance with the common practice in the industry, various features are not drawn to scale. In fact, the dimensions of the various features may be arbitrarily increased or reduced for clarity of illustration and discussion.

FIG. 1 is a diagram schematically illustrating a CIM system of a memory device, in accordance with some embodiments.

FIG. 2 is a diagram schematically illustrating an N:M sparsity scheme, in accordance with some embodiments.

FIG. 3 is a diagram schematically illustrating a process of performing multiply-accumulate operations according to an N:M sparsity scheme, in accordance with some embodiments.

FIG. 4 is a flowchart of a method of performing multiply-accumulate (MAC) operations in a CIM system according to an N:M sparsity scheme, in accordance with some embodiments.

FIG. 5A is a diagram schematically illustrating a system performing MAC operations in a CIM system according to an N:M sparsity scheme, in accordance with some embodiments.

FIG. 5B is a diagram schematically illustrating a structure of a multiplexer, in accordance with some embodiments.

FIG. 6A is a diagram schematically illustrating an N:M sparsity scheme, in accordance with some embodiments.

FIG. 6B is a diagram schematically illustrating a system performing MAC operations in a CIM system by according to an N:M sparsity scheme, in accordance with some embodiments.

FIG. 6C is a diagram schematically illustrating a structure of a multiplexer, in accordance with some embodiments.

FIG. 7A is a diagram schematically illustrating an N:M sparsity scheme, in accordance with some embodiments.

FIG. 7B is a diagram schematically illustrating a system performing MAC operations in a CIM system according to an N:M sparsity scheme, in accordance with some embodiments.

FIG. 7C is a diagram schematically illustrating a structure of a multiplexer, in accordance with some embodiments.

FIGS. 8 and 9 are diagrams schematically illustrating systems performing MAC operations in a CIM system according to an N:M sparsity scheme, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “about” and “substantially” can refer to a percentage of the values as interpreted by those skilled in relevant art(s) in light of the teachings herein.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

Artificial intelligence (AI) models, such as machine learning, deep learning, convolutional neural networks (CNNs), and large language models, can involve large scale multiply-accumulate (MAC) operations. AI applications, such as image classification, object detection, and natural language processing, can require multiplication of the input data with billions or trillions of weights and addition of the multiplication products of similar scale. With dramatically increasing size, AI models can introduce significant challenges for their efficient deployment in AI applications, impacting hardware resource utilization and overall throughput. Moreover, AI applications may require importing and exporting data between processing devices (such as central processing units (CPUs) or graphics processing units (GPUs)) and data storage devices (e.g., memory devices storing the input data and the weights). The large-scale data communication between different devices can pose a bottleneck to improve the performance of the AI applications.

The embodiments described herein are directed to overcome the challenges mentioned above by incorporating N:M sparsity schemes in compute-in-memory (CIM) systems. CIM is a computer architecture in which data operations are available within a memory device, rather than being performed in external processors (such as CPUs or GPUs). In particular, CIM systems can perform MAC operations within memory devices. An N:M sparsity scheme is an approach for improving the performance of AI applications by selecting portions of the weights and the corresponding portions of the input data for the MAC operations. For example, a 2:4 sparsity scheme can improve the throughput of MAC operations and save hardware resources by about 50%, while maintaining accuracy across various AI applications.

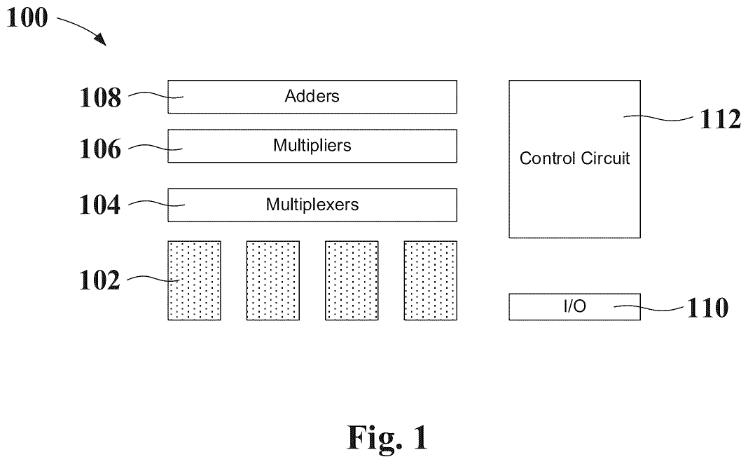

A CIM system 100 is schematically described in FIG. 1, according to some embodiments. CIM system 100 can be included in a memory device (e.g., a memory chip). For example, CIM system 100 can be an integrated circuit including multiple circuits. As shown in FIG. 1, CIM system 100 can include one or more memory arrays 102, a multiplexer circuit 104, a multiplier circuit 106, an adder circuit 108, an input/output (I/O) circuit 110, and a control circuit 112. These circuits can electrically couple with each other by interconnects such as power lines and data/signal transmission buses. In some embodiments, in the memory device that includes CIM system 100, the transfer of data among the circuits of CIM system 100 is performed within the memory device. Put differently, the performance of operations by CIM system 100 (as described below) does not transfer data between the memory device and an external processing device, according to some embodiments.

Referring to FIG. 1, memory arrays 102 can include one or more memory arrays (e.g., static random access memory (SRAM) arrays) for data storage. For example, memory arrays 102 can be configured to store weights used in multiply-accumulate (MAC) operations. For example, the weights can be supplied to multiplier circuit 106 for the MAC operations. In some embodiments, the weights can be organized in arrays, which can be sparse with portions of the weights having zero or relatively small values so that they have small or negligible contributions to the sums of the MAC operations. For such sparse arrays, only a subset of the weights that include members with relatively large values have a substantial contribution to the sums. The subset of the weights, together with their indices, can also be stored in memory arrays 102. In some embodiments, the subset of the weights, rather than the entirety of the weights, can be provided to multiplier circuit 106 to perform the MAC operations, in order to save calculation resources and improve the efficiency of the MAC operations. In some embodiments, the subset of weights can be stored in a first portion of memory arrays 102, and their indices can be stored in a second portion of memory arrays 102. In some embodiments, memory arrays 102 can also be configured to store input data to be processed by the MAC operations. For example, the input data can be image data, text data, or any data to be processed in artificial intelligence (AI) models, such as a machine learning model, a deep learning model, a multilayer neural network model, a large language model, and a generative AI model. In particular, the input data can be multiplied by the weights element-wise in the MAC operations. In some embodiments, the input data can be stored in a third portion of memory arrays 102. In some embodiments, instead of being stored in memory array 102, the input data can be provided externally through I/O circuit 110.

In some embodiments, a portion of the input data, if multiplied by those weights with zero or relatively small values, have negligible contribution to the sums of the MAC operations, and their participation in the MAC operations can be omitted in order to save calculation resources and improve the efficiency of the MAC operations. Accordingly, a sparse portion of the input data corresponding to the subset of weights with non-zero or relatively large values can be selected to participate in the MAC operations. In some embodiments, such a selection process can be performed by multiplexer circuit 104 based on the indices. For example, the indices and the input data can be supplied to multiplexer circuit 104, which can select a subset of the input data corresponding to the subset of the weights, and provide a subset of the input data to multiplier circuit 106 for the MAC operations. In some embodiments, multiplexer circuit 104 can include a number of multiplexer circuits.

Referring to FIG. 1, multiplier circuit 106 can be configured to perform the ‘multiplication’ step of the MAC operations. In some embodiments, multiplier circuit 106 can be configured to perform element-wise multiplication operations on arrays of data. For example, given a first array A(0:n−1) and a second array B(0:n−1), each including n data, multiplier circuit 106 can perform n multiplication operations including A(0)×B(0)=C(0), A(1)×B(1)=C(1), A(2)×B(2)=C(2), . . . , A(n−1)×B(n−1)=C(n−1). Multiplier circuit 106 can output a third array C(0:n−1) including n products to adder circuit 108.

Referring to FIG. 1, adder circuit 108 can be configured to perform the ‘addition’ step of the MAC operations. For example, adder circuit 108 can be configured to add C(0), C(1), C(2), . . . , C(n−1) together and provide a sum S=C(0)+C(1)+C(2)+ . . . +C(n−1). In some embodiments, adder circuit 108 can provide S to I/O circuit as the output of CIM system 100. In some embodiments, adder circuit 108 can send S to memory arrays 102 for storage and for subsequent calculation.

Referring to FIG. 1, control circuit 112 is configured to control the CIM system 100. Control circuit 112 provides command signals to other ICs of CIM system 100 and controls their operations. For example, control circuit 112 can control memory arrays 102 to supply stored weights to multiplier circuit 106 for multiplication operations. Control circuit 112 can control memory arrays 102 to supply stored indices to multiplexer circuit 104 to select the input data before supplying the input data for multiplication operations. Control circuit 112 can control I/O circuit 110 to supply input data to multiplexer circuit 104 to be selected by the indices. Control circuit 112 can control multiplexer circuit 104 to supply selected input data to multiplexer circuit 104 for multiplication operations. Control circuit 112 can control multiplier circuit 106 to perform multiplication operations on the weights and the selected input data, and to provide products of the multiplication operations to adder circuit 108. Control circuit 112 can control adder circuit 108 to perform addition operations on the products and to provide a sum of the products to I/O circuit 110 to output the sum, or to memory arrays 102 to store the sum.

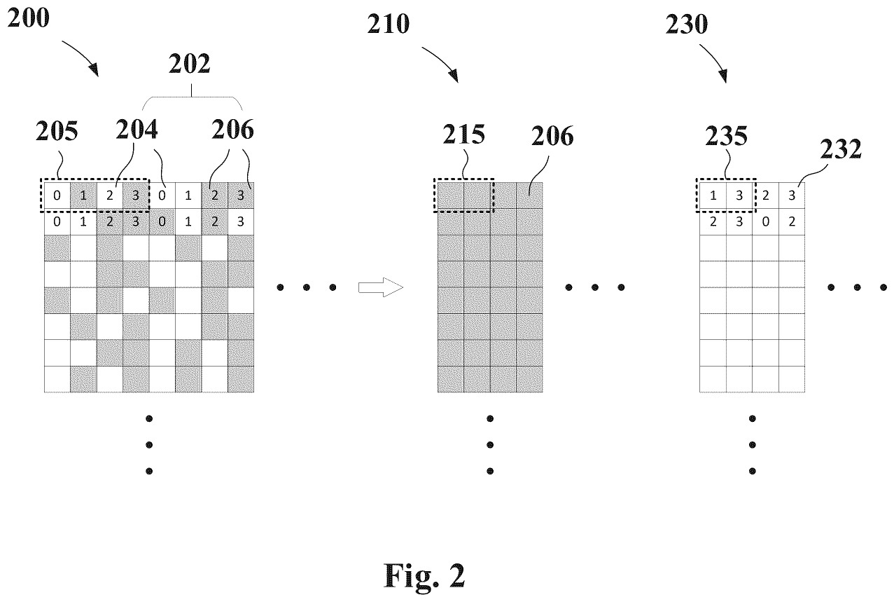

FIG. 2 is a diagram schematically illustrating an N:M sparsity scheme, in accordance with some embodiments. Here, M and N are integers, with N<M. In the N:M sparsity scheme, an array of data can be organized in groups, each including M data. Within each group, only N out of the M data are selected for data processing (e.g., to perform MAC operations), with the rest M-N data excluded. The data can be the weights stored in memory arrays 102 as shown in FIG. 1. FIG. 2 particularly shows an example with N=2 and M=4. In this 2:4 sparsity scheme, an array of weights 200 is organized in groups 205, each including 4 weights 202. Within group 205, two weights 206 (indicated by grey color) are selected for data processing, while the other two weights 204 (indicated by white color) are not. In this disclosure, weights 206 may also be referred to as ‘selected weights 206.’ The rule to determine which two out of the four are selected depends on the actual applications. In some embodiments, values of the four weights 202 within a group 205 can be compared to determine which weights are selected. For example, the two weights with greater values can be selected as weights 206, leaving the other two weights with smaller values as unselected weights 204. Note that in FIG. 2, the numbers 0, 1, 2, 3 in array of weights 200 are the indices of weights 202 within group 205, rather than the values of weights 202.

In some embodiments, weights 206 can be rearranged to form a subset 210 of weights 200, in which weights 206 are organized in groups 215 corresponding to groups 205. Subset 210 is also referred to as array of weights 210. In some embodiments, array of weights 210 can be separately stored in memory arrays 102 as shown in FIG. 1. Accordingly, the indices of weights 206 are also arranged into an array of indices 230, in which indices 232 are organized in groups 235 corresponding to groups 215. In some embodiments, array of indices 230 can also be stored in memory arrays 102 as shown in FIG. 1. Groups 205 are associated with groups 215 in a one-to-one mapping relationship. Similarly, groups 215 are associated with groups 235 in a one-to-one mapping relationship. After the sparsity scheme, array of weights 210 and array of indices 230 can be used to perform MAC operations.

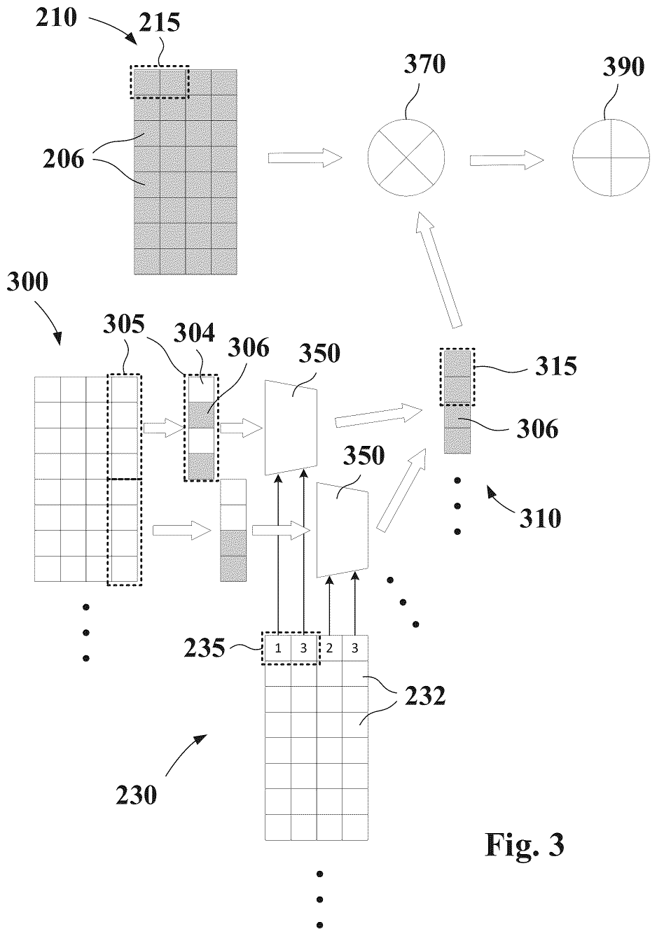

FIG. 3 is a diagram schematically illustrating a process of performing MAC operations according to an N:M sparsity scheme, in accordance with some embodiments. In particular, FIG. 3 shows an example with N=2 and M=4, the same as in FIG. 2. The discussion of elements in FIG. 2 with the same annotations applies to FIG. 3, unless mentioned otherwise.

Referring to FIG. 3, MAC operations can be applied on array of weights 210 and a subset of input data selected from an array of input data 300 according to array of indices 230. In some embodiments, array of input data 300 can be provided by I/O circuit 110 as shown in FIG. 1. In some embodiments, array of input data 300 can also be pre-stored in memory array 102 as shown in FIG. 1. Array of input data 300 can be organized in groups 305 corresponding to groups 205 of weights 200 as shown in FIG. 2. Each group 305 can be provided as signal inputs to a multiplexer 350, which selects two out of the four input data according to indices 232 of a corresponding group 235, which is also supplied to multiplexer 350 as control inputs. Multiplexer 350 can be included in multiplexer circuit 104 as shown in FIG. 1. As shown by the example in FIG. 3, the first group 235 of array of indices 230 includes indices 1 and 3. Accordingly, since the second and fourth input data within the first group 305 have the indices 1 and 3, respectively, they are selected by the first multiplexer 350 as input data 306. Those unselected input data 304 can be excluded for subsequent MAC operations.

In some embodiments, input data 306 can be organized in groups 315 to form a subset 310 of array of input data 300. Subset 310 is also referred to as an array of input data 310. Groups 315 are associated with groups 235 in a one-to-one mapping relationship and are accordingly associated with groups 215 of array of weights 210 in a one-to-one mapping relationship. Array of input data 310 and array of weights 210 can be provided to a multiplier 370, which can perform element-wise multiplication operations. For example, a first weight of a group 215 is multiplied by a first input data of an associated group 315, and a second weight of the group 215 is multiplied by a second input data of the associated group 315. Multiplier 370 can be included in multiplier circuit 106 as shown in FIG. 1. Multiplier 370 can output the products of the element-wise multiplication operations and provide them to an adder 390, which can add the products and provide a sum.

In the examples as described in FIGS. 2 and 3 describe examples with N=2 and M=4 for the N:M sparsity scheme, only 50% of the weights and 50% of the input data are used for the MAC operations. Given that the selected weights have greater values within their groups, the N:M sparsity scheme can capture the major contributions produced by the MAC operations using the entireties of array of weights 200 and array of input data 300 for the MAC operations. Therefore, the N:M sparsity scheme can increase the efficiency or the throughput of the MAC operations by twofold while maintaining acceptable accuracy of the result of the calculation. It should be understood that the combination of the values of M and N can have other options than (4, 2). For example, the combination of (M, N) can also be (4, 1), (4, 3), (8, 4), (8, 3), (8, 2), (16, 8), (16, 4), or (16, 2).

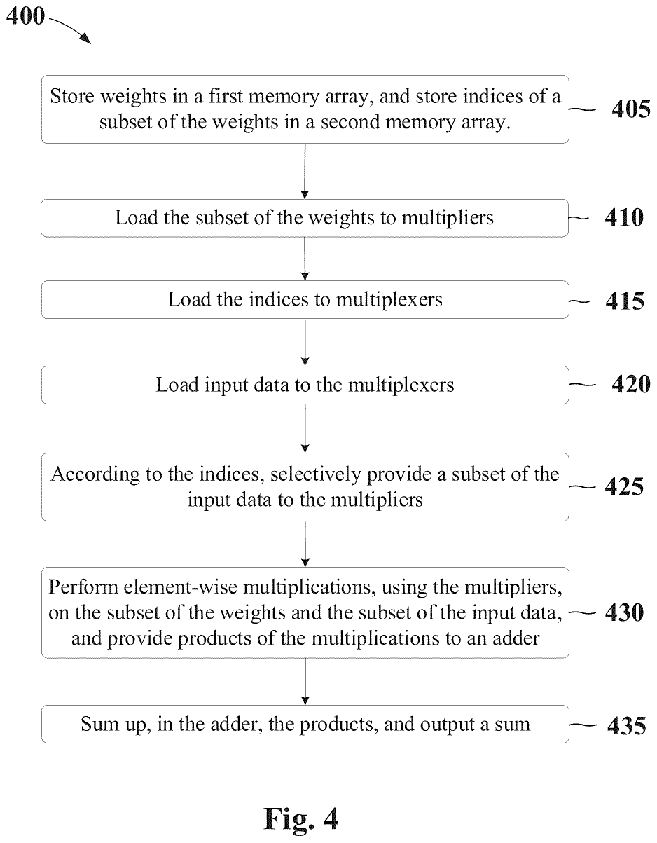

FIG. 4 is a flowchart of a method 400 of performing MAC operations in a CIM system according to an N:M sparsity scheme, in accordance with some embodiments. This disclosure is not limited to this operational description and additional operations may be performed. Other fabrication operations can be performed between the various operations of method 400 and are omitted merely for clarity. Moreover, not all operations may be needed to perform the disclosure provided herein. Additionally, some of the operations may be performed simultaneously, or in a different order than the ones shown in FIG. 4. In some embodiments, one or more other operations may be performed in addition to or in place of the presently described operations. For illustrative purposes, method 400 is described with reference to the system, schemes, and processes shown in FIGS. 1-3.

Referring to FIG. 4, method 400 can begin with operation 405 and the process of storing weights in a first memory array, and store indices of a subset of the weights in a second memory array. For example, as described with reference to FIGS. 1 and 2, array of weights 200 can be stored in a first memory array and array of indices 230 corresponding to array of weights 210 (a subset of array of weights 200) can be stored in a second memory array. In some embodiments, the first and second memory arrays can be two different memory arrays 102 as shown in FIG. 1. In some embodiments, the first and second memory arrays can be different portions of the same memory array 102. In some embodiments, operation 405 can further include storing array of weights 210 in a third memory array. For example, array of weights 210 can be stored in a memory array 102 different from those storing array of weights 200 and array of indices 230. In some embodiments, array of weights 210 can be stored in the same memory array 102 that stores array of weights 200 and/or array of indices 230, but in a different portion.

Referring to FIG. 4, method 400 can continue with operation 410 and the process of loading the subset of weights to multipliers. For example, array of weights 210, which is a subset of array of weights 200, can be provided to multipliers 370 in multiplier circuit 106, as described with reference to FIGS. 1 and 3.

Referring to FIG. 4, method 400 can continue with operation 415 and the process of loading the indices to multiplexers. For example, array of indices 230 stored in memory array 102 can be provided as control inputs to multiplexers 350 in multiplexer circuit 104, as described with reference to FIGS. 1 and 3.

Referring to FIG. 4, method 400 can continue with operation 420 and the process of loading input data to the multiplexers. For example, array of input data 300 can be provided as signal inputs to multiplexers 350 in multiplexer circuit 104, as described with reference to FIGS. 1 and 3.

Referring to FIG. 4, method 400 can continue with operation 425 and the process of selectively providing a subset of the input data to the multipliers, based on the indices. For example, based on array of indices 230 as the control inputs, multiplexers 350 can select array of input data 310 as a subset out of array of input data 300 as the signal inputs and can provide array of input data 310 as signal outputs to multiplier 370, as described with reference to FIGS. 1 and 3.

Referring to FIG. 4, method 400 can continue with operation 430 and the process of multiplying the subset of the weights and the subset of the input data in an element-wise manner using the multipliers, and provide products of the multiplications to an adder. For example, multiplier 370 can multiply corresponding elements between array of weights 206 and array of input data 310 to generate products of the multiplications, and provide the products to adder 390 in adder circuit 108, as described with reference to FIGS. 1 and 3.

Referring to FIG. 4, method 400 can continue with operation 435 and the process of summing the products using the adder. For example, adder 390 can add the products together and generate a sum, described with reference to FIGS. 1 and 3. In some embodiments, operation 435 can also include providing the sum to I/O circuit 110 for output. In some embodiments, operation 435 can also include storing the sum to memory array 102 for subsequent data processing.

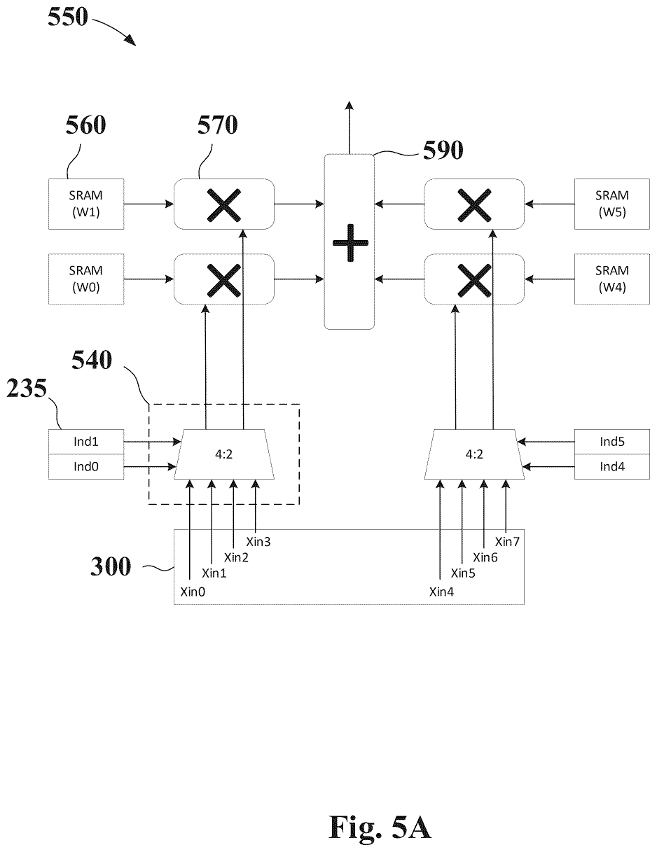

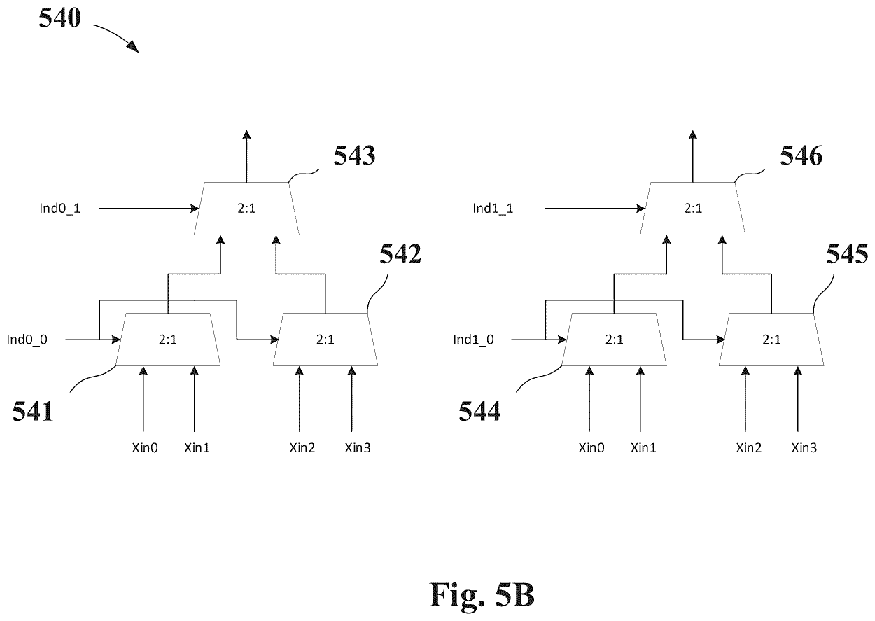

FIGS. 5A-8B illustrate embodiments of systems that implement method 400 to perform MAC operations in a CIM system according to an N:M sparsity scheme. The discussion of elements in FIGS. 1-3 with the same annotations applies to FIGS. 5A-8B, unless mentioned otherwise.

FIG. 5A is a diagram schematically illustrating a system 550 performing MAC operations in a CIM system according to an N:M sparsity scheme, in accordance with some embodiments. System 550 includes SRAM circuits 560, multiplexer circuits 540, multiplier circuits 570, and an adder circuit 590. In some embodiments, system 550 can be included in system 100, as shown in FIG. 1. For example, memory array 102 can include SRAM circuits 560, multiplexer circuit 104 can include multiplexer circuits 540, multiplier circuits 106 can include multiplier circuits 570, and adder circuit 108 can include adder circuit 590. In particular, FIG. 5A illustrates an example with M=4 and N=2. SRAM circuits 560 can store a group of two weights, including W0 and W1. The group of two weights can be a subset of a group of four weights (e.g., group 215 as a subset of group 205 as shown in FIG. 2). Each of the weights W0 and W1 can be provided to a multiplier circuit 570 as an input.

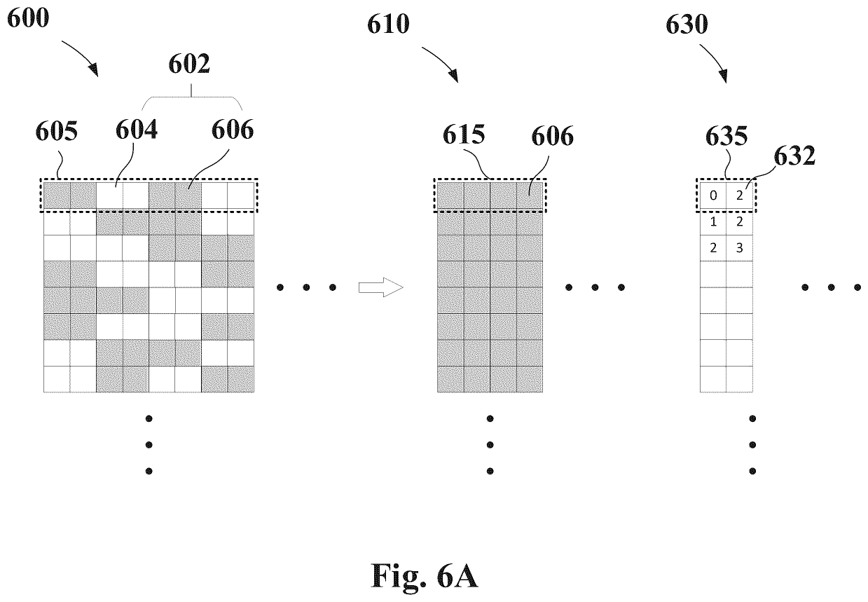

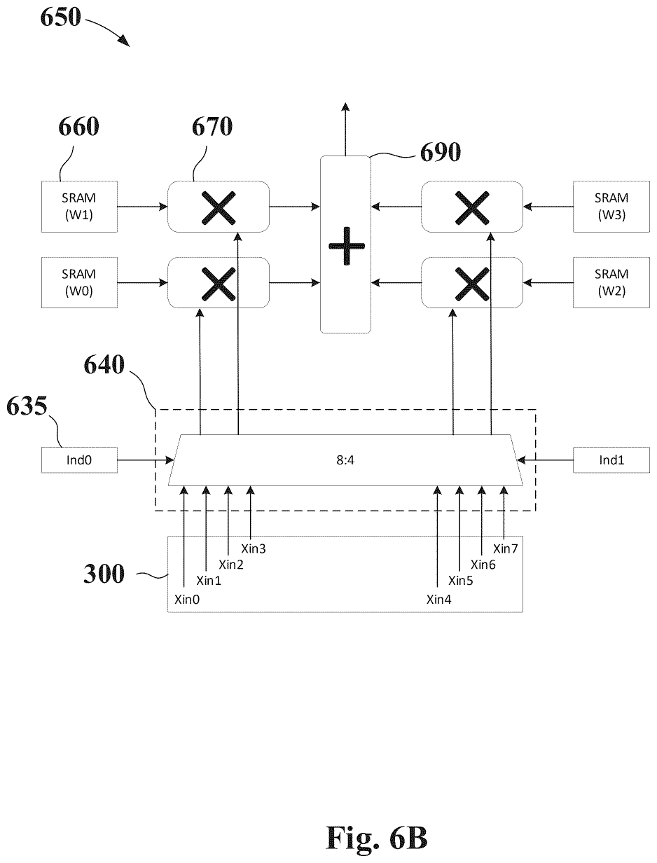

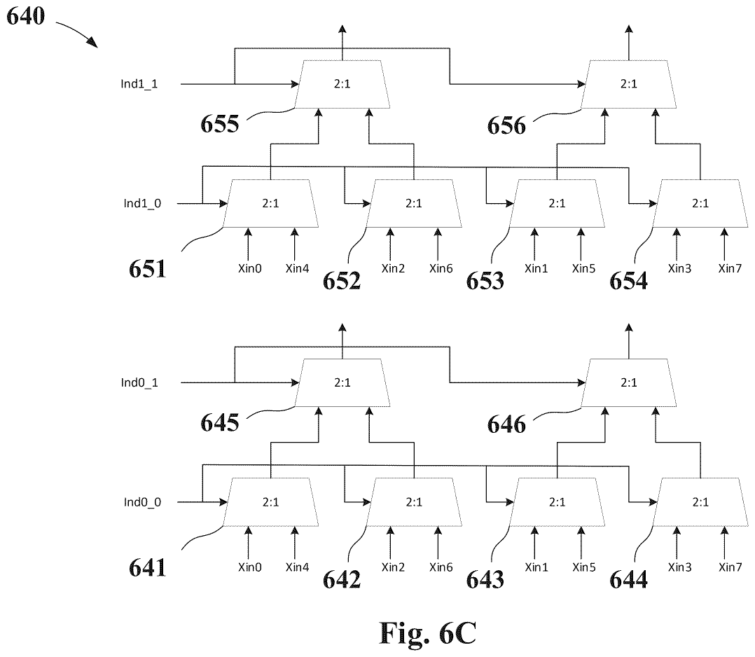

Each multiplexer circuit 540 has four signal inputs, two control inputs, and two signal outputs. The four signal inputs of multiplexer circuit 540 can be provided with a group of four input data from array of data 300 and including data Xin0-Xin3. For example, the group of four input data can be group 305 as shown in FIG. 3. The two control inputs of multiplexer circuit 540 can be provided with a group 235 with two indices Ind0 and Ind1, which indicate addresses of the weights W0 and W1 in the associated group of four weights (e.g., an associated group 205 of array of weights 200, as shown in FIG. 2). The two signal outputs of multiplexer circuit 540 can provide a group of two input data selected from the group of four input data. In the example shown in FIG. 6B, the selected group of two input data includes Xin0 and Xin1, according to the two indices Ind0 and Ind1, with Xin2 and Xin3 unselected. Xin0 and Xin1 are then provided separately to the two multiplier circuits 570 and multiplied by W0 and W1 element-wise (i.e., Xin0×W0 and Xin1×W1). The products of the multiplication generated by multiplier circuits 570 are then provided to adder circuit 590 to be summed.

Similarly, the same process can apply on the right hand side of FIG. 5A, where weights W4 and W5 can be multiplied in an element-wise manner by input data Xin4 and Xin5 selected from a group of input data including Xin4, Xin5, Xin6, and Xin7, according to indices Ind4 and Ind5.

Each of the multiplexer circuits 540 as shown in FIG. 5A is a 4:2 multiplexer that can select two out of the four signal inputs and provide them at the output. FIG. 5B is a diagram schematically illustrating a structure of a 4:2 multiplexer, in accordance with some embodiments. As shown in FIG. 5B, multiplexer circuit 540 can include two sets of multiplexers in parallel. Each set can include three multiplexers in total, each of which is a 2:1 multiplexer including two signal inputs, one control input, and one signal output. Specifically, the first set can include multiplexers 541-543 with Ind0 being their control input, and the second set can include multiplexers 544-546 with Ind1 being their control input. In addition, each of the indices Ind0 and Ind1 can be represented by a two-digit binary number. For example, Ind0 can include a first bit Ind0_0 and a second bit Ind0_1, and Ind1 can include a first bit Ind1_0 and a second bit Ind1_1.

Among the first set of multiplexers 541-543, multiplexer 541 takes Xin0 and Xin1 as signal inputs, multiplexer 542 takes Xin2 and Xin3 as signal inputs, and both multiplexers 541 and 542 take Ind0_0 as the control input. Multiplexer 543 takes the outputs of multiplexers 541 and 542 as signal inputs and Ind0_1 as the control input. Each of the multiplexers 541-543 outputs the input data provided to one of the signal input (e.g., to the one on the left hand side) if the control input is 0 and outputs the input data provided to the other signal input (e.g., the one on the right hand side) if the control input is 1. For example, if Ind0=00, multiplexer 541 can output Xin0, multiplexer 542 can output Xin2, and multiplexer 543 can subsequently output Xin0. If Ind0=01, multiplexer 541 can output Xin0, multiplexer 542 can output Xin2, and multiplexer 543 can subsequently output Xin2. If Ind0=10, multiplexer 541 can output Xin1, multiplexer 542 can output Xin3, and multiplexer 543 can subsequently output Xin1. If Ind0=11, multiplexer 541 can output Xin1, multiplexer 542 can output Xin3, and multiplexer 543 can subsequently output Xin3. The same discussion applies to the second set of multiplexers 544-546. Referring to FIG. 5A, multiplexer circuit 540 provided with input data Xin4-Xin7 can have the same structure as shown in FIG. 5B. According to the above mechanism, the outputs of the two multiplexer circuits 540 can be governed by the following truth table according to the values of the control inputs Ind0, Ind1, Ind4, and Ind5.

| Ind0, Ind1, Ind4, Ind5 | Output of multiplexer circuits 540 |
|---|---|
| 00, 01, 00, 01 | Xin0, Xin1, Xin4, Xin5 |
| 00, 10, 01, 10 | Xin0, Xin2, Xin5, Xin6 |
| 00, 11, 10, 11 | Xin0, Xin3, Xin6, Xin7 |
| 10, 11, 01, 11 | Xin2, Xin3, Xin5, Xin7 |
| . . . | . . . |

In some embodiments, the N:M sparsity scheme as shown in FIG. 2 can be modified by changing a ‘granularity’ of the selected N weights out of the M weights. FIG. 6A is a diagram schematically illustrating an N:M sparsity scheme with a different granularity compared to that in FIG. 2, in accordance with some embodiments. FIG. 6A shows an example with N=4 and M=8. In this 4:8 sparsity scheme, an array of weights 600 is organized in groups 605, each including eight weights 602, among which four weights 606 (indicated by grey color) are selected for data processing, while the other four weights 604 (indicated by white color) are not. Within group 605, adjacent two weights are paired, forming four pairs in total, and the two weights in each pair are either selected or unselected together. For example, in each group 605, weights 604 include two pairs of unselected weights, and weights 606 include two pairs of selected weights. Viewing each pair as an elemental unit (or a ‘grain’) with a grain size equal to 2, the granularity of this 4:8 sparsity scheme is coarser compared to that of the 2:4 sparsity scheme with a grain size equal to 1, as shown in FIG. 2. The rule to determine which two out of the four pairs in a group 605 are selected depends on the actual applications. In some embodiments, an average value of the two weights in each pair can be calculated, and the average values of the pairs within a group 605 can be compared to determine which pairs are selected. For example, the two pairs with greater average values can be selected as weights 606, leaving the other two pairs with smaller average values as unselected weights 604.

In some embodiments, weights 606 can be rearranged to form a subset 610 of array of weights 600, in which weights 606 are organized in groups 615 corresponding to groups 605. Subset 610 is also referred to as array of weights 610. In some embodiments, array of weights 610 can also be stored in memory arrays 102 as shown in FIG. 1.

Since adjacent weights in arrays of weights are paired, it is sufficient to index the pairs, rather than the weights. For example, an index having a value of 0, 1, 2, or 3 can respectively indicate the first, second, third, or fourth pairs within a group 605. Accordingly, indices 632 can also be arranged into an array of indices 630, in which the indices are organized in groups 635 corresponding to groups 615. Each group 635 includes two indices indicating two pairs (four weights). In some embodiments, array of indices 630 can also be stored in memory arrays 102 as shown in FIG. 1. Compared to the sparsity scheme as shown in FIG. 2 with a finer granularity, array of indices 630 is half the size of array of indices 230 and can reduce the hardware and power resources for storage. Groups 605 are associated with groups 615 in a one-to-one mapping relationship. Similarly, groups 615 are associated with groups 635 in a one-to-one mapping relationship. After the sparsity scheme, array of weights 610 and array of indices 630 can be used to perform the MAC operations.

FIG. 6B is a diagram schematically illustrating a system 650 performing MAC operations in a CIM system according to an N:M sparsity scheme, in accordance with some embodiments. System 650 includes SRAM circuits 660, a multiplexer circuit 640, multiplier circuits 670, and an adder circuit 690. In some embodiments, system 650 can be included in system 100, as shown in FIG. 1. For example, memory array 102 can include SRAM circuits 660, multiplexer circuit 104 can include multiplexer circuits 640, multiplier circuits 106 can include multiplier circuits 670, and adder circuit 108 can include adder circuit 690. In particular, FIG. 6B illustrates an example with M=8 and N=4 and the granularity with the grain size equal to 2. SRAM circuits 660 store a group of two pairs (or a group of four weights), including (W0, W1) and (W4, W5). The group of four weights can be a subset of a group of eight weights (e.g., group 615 as a subset of group 605 as shown in FIG. 6A). Each of the weights W0, W1, W2, and W3 can be provided to a multiplier 670 as an input.

Multiplexer circuit 640 can be an 8:4 multiplexer having eight signal inputs, two control inputs, and four signal outputs. The eight signal inputs of multiplexer circuit 640 can be provided with a group of eight input data (e.g., two groups 305 of array of data 300 as shown in FIG. 3), including data Xin0-Xin7. The two control inputs of multiplexer circuit 640 can be provided with a group 635 with two indices Ind0 and Ind1, which indicate addresses of the pairs of weights in the associated group of eight weights. The four signal outputs of multiplexer circuit 640 can provide two pairs of input data selected from the group of eight input data. In the example shown in FIG. 6B, the selected pairs of input data include (Xin0, Xin1) and (Xin2, Xin3), according to the two indices Ind0 and Ind1, with the pairs (Xin4, Xin5) and (Xin6, Xin7) unselected. Xin0-Xin3 are then provided separately to the four multiplier circuits 670 and multiplied by W0-W3 element-wise (i.e., Xin0×W0, Xin1×W1, Xin2×W2, and Xin3×W3). The products of the multiplication generated by multiplier circuits 670 are then provided to adder circuit 690 to be summed.

FIG. 6C is a diagram schematically illustrating a structure of multiplexer circuit 640, in accordance with some embodiments. As shown in FIG. 6C, multiplexer circuit 640 can include twelve multiplexers 641-646 and 651-656 forming two sets in parallel. Each set can include six multiplexers in total, each of which is a 2:1 multiplexer including two signal inputs, one control input, and one signal output. Specifically, a first set can include multiplexers 641-646 with Ind0 being their control input, and a second set can include multiplexers 651-656 with Ind1 being their control input. In addition, each of the indices Ind0 and Ind1 can be represented by a two-digit binary number. For example, Ind0 can include a first bit Ind0_0 and a second bit Ind0_1, and Ind1 can include a first bit Ind1_0 and a second bit Ind1_1.

Among the first set of multiplexers 641-646, multiplexer 641 can take Xin0 and Xin4 as signal inputs, multiplexer 642 can take Xin2 and Xin6 as signal inputs, multiplexer 643 can take Xin1 and Xin5 as signal inputs, and multiplexer 644 can take Xin3 and Xin7 as signal inputs. Multiplexers 641-644 can take Ind0_0 as the control input. Multiplexer 645 can take the outputs of multiplexers 641 and 642 as signal inputs and Ind0_1 as the control input. Multiplexer 646 can take the outputs of multiplexers 643 and 644 as signal inputs and Ind0_1 as the control input. Each of the multiplexers 641-646 can output an input data provided to one of the signal input (e.g., to the one on the left hand side) if the control input is 0 and can output another input data provided to the other signal input (e.g., the one on the right hand side) if the control input is 1. For example, if Ind0=00, multiplexer 641 can output Xin0, multiplexer 642 can output Xin2, multiplexer 643 can output Xin1, multiplexer 644 can output Xin3, multiplexer 645 can output Xin0, and multiplexer 646 can output Xin1. As a result, the first set of multiplexers 641-646 can select the pair of input data (Xin0, Xin1). In another example, if Ind0=01, multiplexer 641 can output Xin0, multiplexer 642 can output Xin2, multiplexer 643 can output Xin1, multiplexer 644 can output Xin3, multiplexer 645 can output Xin2, and multiplexer 646 can output Xin3. As a result, the first set of multiplexers 641-646 can select the pair of input data (Xin2, Xin3). Similarly, if Ind0=10 or 11, the first set of multiplexers 641-646 can select the pair of input data (Xin4, Xin5) or (Xin6, Xin7), respectively. The same discussion applies to the second set of multiplexers 651-656 and is not repeated. According to the above mechanism, the outputs of multiplexer circuit 640 can be governed by the truth table below according to the value of the control inputs Ind0 and Ind1.

| Ind0, Ind1 | Outputs of multiplexer circuit 640 |
|---|---|
| 00, 01 | Xin0, Xin1, Xin2, Xin3 |
| 01, 11 | Xin2, Xin3, Xin6, Xin7 |
| 10, 11 | Xin4, Xin5, Xin6, Xin7 |
| 01, 10 | Xin2, Xin3, Xin4, Xin5 |
| . . . | . . . |

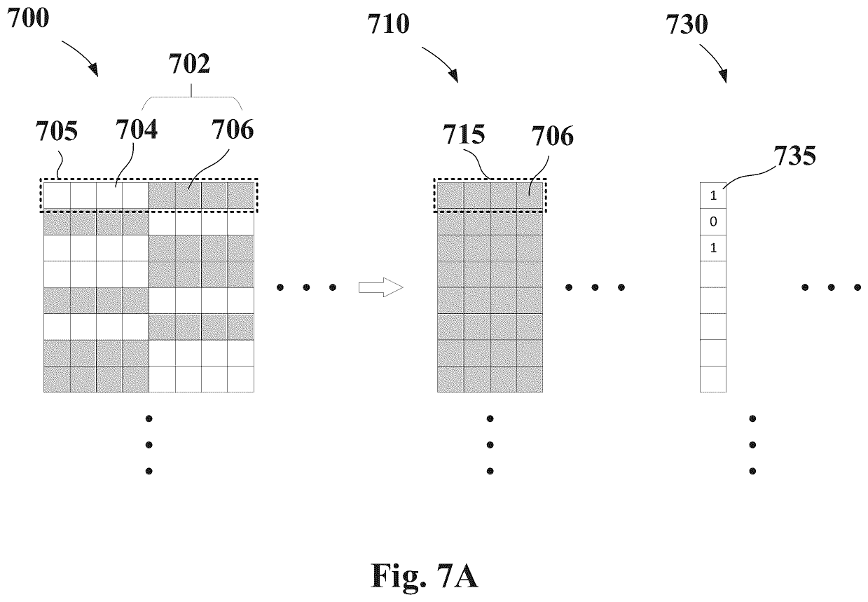

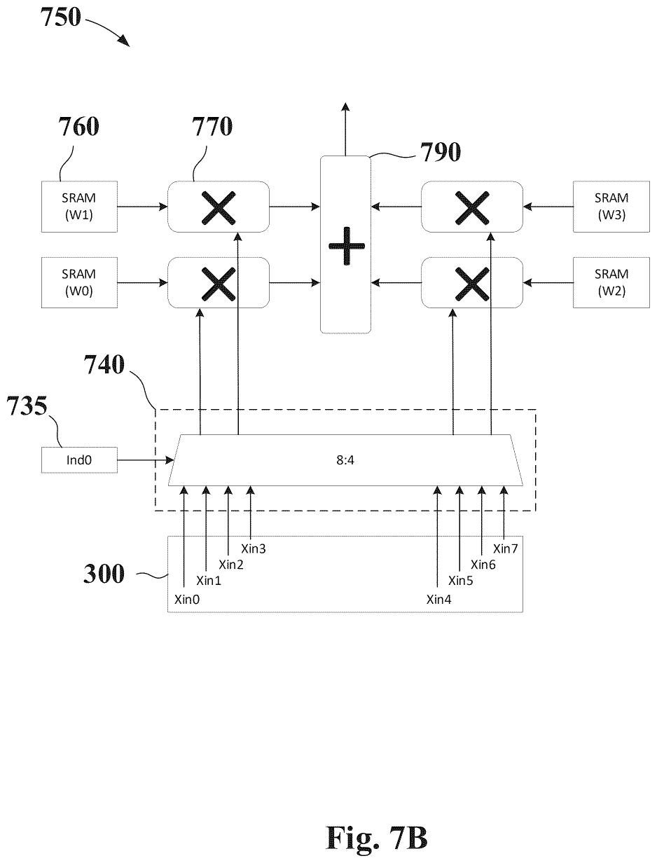

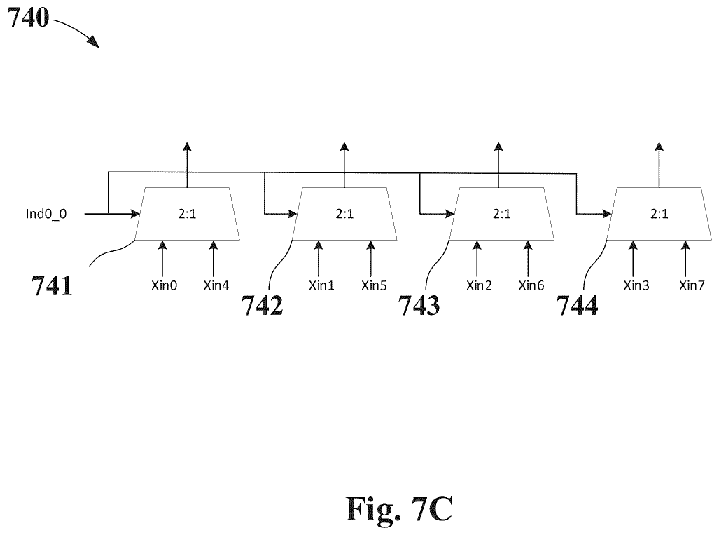

FIG. 7A is a diagram schematically illustrating an N:M sparsity scheme with a different granularity compared to those in FIGS. 2 and 6A, in accordance with some embodiments. FIG. 7A shows an example with N=4 and M=8. In this 4:8 sparsity scheme, an array of weights 700 is organized in groups 705, each including eight weights 702, among which four weights 706 (indicated by grey color) are selected for data processing, while the other four weights 704 (indicated by white color) are not. Each group 705 is further divided into two subgroups, with the first subgroup including the four adjacent weights on the left hand side and the second subgroup including the other four adjacent weights on the right hand side. The sparsity scheme is implemented with the four weights in one of the two subgroups being selected. Viewing each subgroup as a grain having a grain size equal to 4, the granularity of this 4:8 sparsity scheme is coarser than that shown in FIG. 6A. The rule to determine which one of the two subgroups in group 705 is selected depends on the actual applications. In some embodiments, an average value of the four weights in each subgroup can be calculated, and the average values of the subgroups within a group 705 can be compared to determine which subgroup is selected. For example, the subgroup with a greater average value can be selected as weights 706, leaving the other subgroup with a smaller average value as unselected weights 704.

In some embodiments, weights 706 can be rearranged to form a subset 710 of array of weights 700, in which weights 706 are organized in groups 715 corresponding to groups 705. Subset 710 is also referred to as array of weights 710. In some embodiments, array of weights 710 can also be stored in memory arrays 102 as shown in FIG. 1.

Since weights in arrays of weights are organized in subgroups, it is sufficient to index the subgroups, rather than the weights. For example, an index having a value of 0 or 1 can indicate the first subgroup or the second subgroup within group 705, respectively. Accordingly, indices 735 can also be arranged into an array of indices 730, in which each index 735 corresponds to one of the groups 715. In some embodiments, array of indices 730 can also be stored in memory arrays 102 as shown in FIG. 1. Compared to the sparsity scheme with a finer granularity as shown in FIG. 6A, array of indices 730 is half the size of array of indices 630 and can reduce the hardware and power resources for storage. Groups 705 are associated with groups 715 in a one-to-one mapping relationship. Similarly, groups 715 are associated with indices 735 in a one-to-one mapping relationship. After the sparsity scheme, array of weights 710 and array of indices 730 can be used to perform the MAC operations.

FIG. 7B is a diagram schematically illustrating a system 750 performing MAC operations in a CIM system according to an N:M sparsity scheme, in accordance with some embodiments. System 750 includes SRAM circuits 760, a multiplexer circuit 740, multiplier circuits 770, and an adder circuit 790. In some embodiments, system 750 can be included in system 100, as shown in FIG. 1. For example, memory array 102 can include SRAM circuits 760, multiplexer circuit 104 can include multiplexer circuits 740, multiplier circuits 106 can include multiplier circuits 770, and adder circuit 108 can include adder circuit 790. In particular, FIG. 7B illustrates an example with M=8 and N=4 and a granularity with grain size equal to 4. SRAM circuits 760 stores four weights (W0, W1, W2, W3) within a subgroup. The subgroup of four weights can be a subset of a group of eight weights (e.g., group 715 as a subset of group 705 as shown in FIG. 7A). Each of the weights W0, W1, W2, and W3 can be provided to a multiplier circuit 770 as an input.

Multiplexer circuit 740 can be an 8:4 multiplexer having eight signal inputs, one control input, and four signal outputs. The eight signal inputs of multiplexer circuit 640 can be provided with a group of eight input data (e.g., two groups 305 of array of data 300 as shown in FIG. 3) including data Xin0-Xin7. The control input of multiplexer circuit 740 can be provided with an index 735 (e.g., Ind0), which indicates one of the two subgroups in the associated group of eight weights. The four signal outputs of multiplexer circuit 640 can provide the selected four input data from the group of eight input data. In the example shown in FIG. 7B, the four selected input data include Xin0, Xin1, Xin2, and Xin3, according to the index Ind0, with the other four input data Xin4, Xin5, Xin6, and Xin7 unselected. Xin0-Xin3 are then provided separately to the four multiplier circuits 770 and multiplied by W0-W3 element-wise (i.e., Xin0×W0, Xin1×W1, Xin2×W2, and Xin3×W3). The products of the multiplication generated by multiplier circuits 770 are then provided to adder circuit 790 to be summed.

FIG. 7C is a diagram schematically illustrating a structure of multiplexer circuit 740, in accordance with some embodiments. As shown in FIG. 7C, multiplexer circuit 740 can include four multiplexers 741-744 in total, each of which is a 2:1 multiplexer including two signal inputs, one control input, and one signal output. Multiplexers 741-744 take Ind0 as their control input, which can be represented by a single-digit binary number. For example, Ind0 can be 0 or 1. Multiplexer 741 can take Xin0 and Xin4 as signal inputs. Multiplexer 742 can take Xin1 and Xin5 as signal inputs. Multiplexer 643 can take Xin2 and Xin6 as signal inputs. Multiplexer 744 can take Xin3 and Xin7 as signal inputs. Each of the multiplexers 741-744 can output an input data provided to one of the signal input (e.g., to the one on the left hand side) if the control input is 0 and can output another input data provided to the other signal input (e.g., the one on the right hand side) if the control input is 1. For example, if Ind0=0, multiplexer 741 can output Xin0, multiplexer 742 can output Xin1, multiplexer 743 can output Xin2, and multiplexer 744 can output Xin3. As a result, multiplexer circuit 740 can select the subgroup of input data (Xin0, Xin1, Xin2, Xin3). In another example, if Ind0=1, multiplexer 741 can output Xin4, multiplexer 742 can output Xin5, multiplexer 743 can output Xin6, and multiplexer 744 can output Xin7. As a result, multiplexer circuit 740 can select the subgroup of input data (Xin4, Xin5, Xin6, Xin7). According to the above mechanism, the outputs of multiplexer circuit 740 can be governed by the truth table below according to the value of the control inputs Ind0.

| Ind0 | Output of multiplexer circuit 740 |
|---|---|
| 0 | Xin0, Xin1, Xin2, Xin3 |
| 1 | Xin4, Xin5, Xin6, Xin7 |

Comparing multiplexer circuit 740 as shown in FIG. 7C to multiplexer circuit 640 as shown in FIG. 6C, the structure of multiplexer circuit 740 is simpler than multiplexer circuit 640. The MAC operations as shown in FIG. 7B according to the 4:8 sparsity scheme with a coarser granularity spend fewer hardware resources than those as shown in FIG. 6B with a finer granularity. On the other hand, finer granularity can increase the resolutions of the weights and input data, improving the accuracy of the calculation. Practical considerations, such a trade-off between saving hardware resources and improving calculation accuracy, depend on the applications. Although FIGS. 2, 6A, and 7A illustrate examples N:M sparsity scheme with grain sizes being 1, 2, and 4, it should be understood that the grain size can be other suitable numbers.

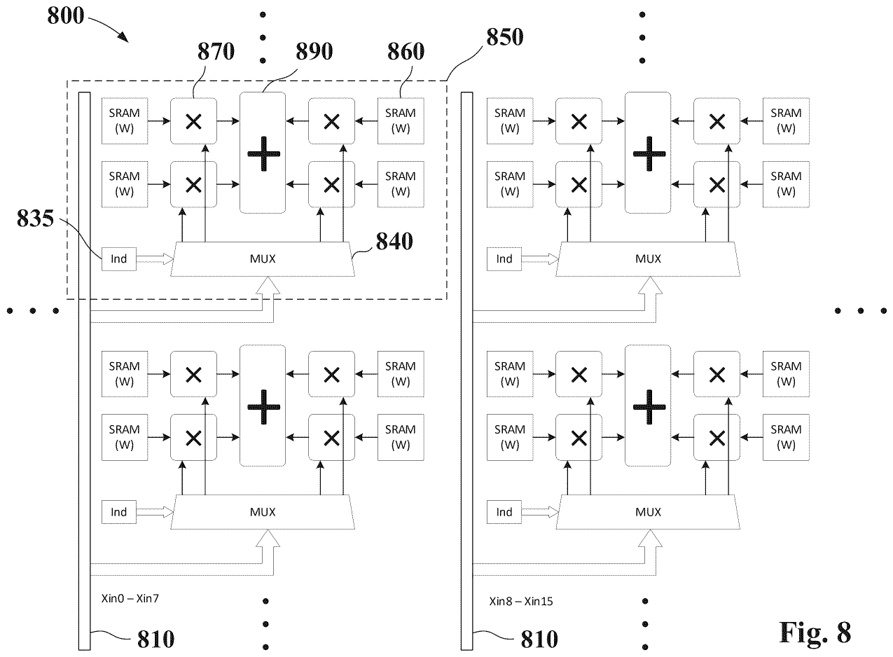

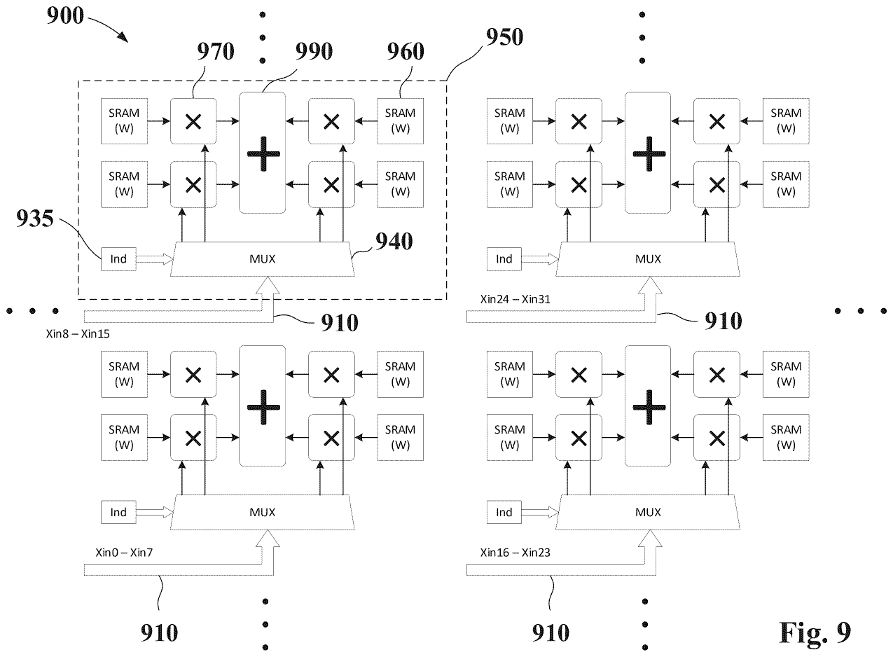

In some embodiments, systems 550, 650, and 750 as shown in FIGS. 5A, 6B, and/or 7B can be scaled up. FIGS. 8 and 9 are diagrams schematically illustrating systems 800 and 900, respectively, each performing MAC operations in a CIM system according to an N:M sparsity scheme. Systems 800 and 900 can include a number of subsystems 850 and 950, respectively. Each subsystem 850 or 950 can include one of systems 550, 650, and 750 as shown in FIGS. 5A, 6B, and/or 7B.

FIG. 8 shows subsystems 850 schematically organized in an array. Subsystem 850 can include SRAM circuits 860, a multiplexer circuit 840, multiplier circuits 870, and an adder circuit 890. In some embodiments, subsystem 850 can be included in system 100, as shown in FIG. 1. For example, memory array 102 can include SRAM circuits 860, multiplexer circuit 104 can include multiplexer circuits 840, multiplier circuits 106 can include multiplier circuits 870, and adder circuit 108 can include adder circuit 890. As shown in FIG. 8, subsystems 850 within the same column of the array can be provided with the same batch of input data and perform MAC operations on the same batch of input data in parallel. For example, system 800 can include data buses 810, which can be coupled to I/O circuit 110 or memory arrays 102 as shown in FIG. 1. Each data bus 810 can broadcast a group of input data (e.g., Xin0-Xin7, Xin8-Xin15, etc.) to subsystems 850 in the same column. In some embodiments, systems 800 can perform parallel MAC operations on the same batches of input data with improved efficiency.

FIG. 9 shows subsystems 950 schematically organized in an array. Subsystem 850 can include SRAM circuits 860, a multiplexer circuit 840, multiplier circuits 870, and an adder circuit 890. In some embodiments, subsystem 850 can be included in system 100, as shown in FIG. 1. For example, memory array 102 can include SRAM circuits 860, multiplexer circuit 104 can include multiplexer circuits 840, multiplier circuits 106 can include multiplier circuits 870, and adder circuit 108 can include adder circuit 890. As shown in FIG. 9, different subsystems 950 can be provided with different batches of input data and perform MAC operations in parallel. For example, system 900 can include data buses 910, which can be coupled to I/O circuit 110 or memory arrays 102 as shown in FIG. 1. Each data bus 910 can provide a group of input data (e.g., Xin0-Xin7, Xin8-Xin15, Xin16-Xin23, Xin24-Xin31, etc.) to different subsystems 950. In some embodiments, systems 800 can perform MAC operations on the input data with improved throughput.

This disclosure is directed to a memory device and a method of implementing multiply-and-accumulate (MAC) operations in the memory device based on an N:M sparsity scheme. The memory device can include a computer in memory (CIM) system, which can include a memory array with a first portion configured to store weights and a second portion configured to store indices associated with the weights. The CIM system can further include a multiplexer circuit, a multiplier circuit, and an adder circuit. The multiplexer circuit can be configured to receive data and the indices, and output a subset of the data based on the indices. The multiplier circuit can be configured to multiply the subset of the data by corresponding weights to generate outputs. The adder circuit can be configured to sum the output.

In some embodiments, a memory device can include a memory array, which can a first portion and a second portion. The first portion can be configured to store a plurality of weights. The second portion can be configured to store a plurality of indices associated with a subset of the plurality of weights. The memory device can further include a multiplexer circuit, which can be configured to receive a plurality of data and the plurality of indices and output a subset of the plurality of data based on the plurality of indices. The memory device can further include a multiplier circuit, which can be configured to multiply the subset of the plurality of data and the subset of the plurality of weights to generate a plurality of products. The memory device can further include an adder circuit configured to sum the plurality of products.

In some embodiments, an integrated circuit can include a first memory array and a second memory array. The first memory array can be configured to store a plurality of weights. The second memory array configured to store a plurality of indices associated with the plurality of weights. The integrated circuit can further include a multiplexer circuit, a multiplier circuit, and an adder circuit. The multiplexer circuit can be configured to receive a plurality of data and the plurality of indices and output a subset of the plurality of data based on the plurality of indices. The multiplier circuit can be configured to multiply the subset of the plurality of data by a subset of the plurality of weights to generate a plurality of products. The adder circuit can be configured to sum the plurality of products.

In some embodiments, a method can include storing a plurality of weights in a first memory array of a memory device and storing a plurality of indices in a second memory array of the memory device. The plurality of indices can be associated with a subset of the plurality of weights. The method can further include providing the subset of the plurality of weights to a multiplier circuit of the memory device, providing a plurality of data to a multiplexer circuit of the memory device, and providing a subset of the plurality of data selected by the multiplexer circuit to the multiplier circuit based on the plurality of indices. The method can further include performing multiplication operations on the subset of the plurality of data and the subset of the plurality of weights to calculate a plurality of products using the multiplier circuit. The method can further include performing an addition operation to calculate a sum of the plurality of products using an adder circuit of the memory device.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a memory array comprising a first portion and a second portion, wherein:
the first portion is configured to store a plurality of weights; and
the second portion is configured to store a plurality of indices associated with a subset of the plurality of weights;
a multiplexer circuit configured to:
receive a plurality of data and the plurality of indices; and
output a subset of the plurality of data based on the plurality of indices;
a multiplier circuit configured to multiply the subset of the plurality of data and the subset of the plurality of weights to generate a plurality of products; and
an adder circuit configured to sum the plurality of products.

2. The memory device of claim 1, wherein the memory array further comprises a third portion configured to store the plurality of data.

3. The memory device of claim 1, wherein the plurality of indices comprise information associated with addresses of the subset of the plurality of weights.

4. The memory device of claim 1, wherein the multiplexer circuit is further configured to output the subset of the plurality of data based on addresses of the subset of the plurality of data, and wherein information associated with the addresses is based on the plurality of indices.

5. The memory device of claim 1, wherein the multiplier circuit is further configured to multiply a data of the subset of the plurality of data and a weight of the subset of the plurality of weights, and wherein an address of the data is the same as an address of the weight.

6. The memory device of claim 1, wherein:
the plurality of weights comprise a plurality of first groups of weights, wherein each first group of weights of the plurality of first groups of weights comprises m weights, and wherein m is an integer number; and
the subset of the plurality of weights comprise a plurality of second groups of weights associated with the plurality of first groups of weights based on a one-to-one mapping relationship, wherein each second group of weights of the plurality of second groups of weights comprises n weights out of the m weights of a first group of weights of the plurality of first groups of weights, and wherein n is an integer number less than m.

7. The memory device of claim 6, wherein:
the plurality of indices comprises a plurality of groups of indices, and wherein each group of indices of the plurality of groups of indices comprises n indices; and
an address of an ith weight of the second group of weights in the first group of weights is indicated by an ith index of a group of indices of the plurality of groups of indices, and wherein i is an integer between 1 and n.

8. The memory device of claim 7, wherein:
the plurality of data comprises a plurality of first groups of data, and wherein each first group of data of the plurality of first groups of data comprises m data;
the subset of the plurality of data comprise a plurality of second groups of data, and wherein each second group of data of the subset of the plurality of groups of data comprises n data; and
a first group of data of the plurality of first groups of data comprises a second group of data of the plurality of second groups of data.

9. The memory device of claim 8, wherein:
an address of an ith data of the second group of data in the first group of data is indicated by the ith index of the group of indices.

10. The memory device of claim 9, wherein the multiplier circuit is further configured to provide a product of the ith data and the ith weight, and wherein the plurality of products comprises the product.

11. The memory device of claim 6, wherein combinations of (m, n) comprise (4, 2), (8, 4), (8, 2), (16, 8), (16, 4), and (16, 2).

12. An integrated circuit, comprising:
a first memory array configured to store a plurality of weights;
a second memory array configured to store a plurality of indices associated with the plurality of weights;
a multiplexer circuit configured to:
receive a plurality of data and the plurality of indices; and
output a subset of the plurality of data based on the plurality of indices;
a multiplier circuit configured to multiply the subset of the plurality of data by a subset of the plurality of weights to generate a plurality of products; and
an adder circuit configured to sum the plurality of products.

13. The integrated circuit of claim 12, wherein the plurality of indices comprise information associated with addresses of the subset of the plurality of weights.

14. The integrated circuit of claim 12, wherein:
the first memory array is configured to store the plurality of weights in a plurality of first groups, wherein each first group of the plurality of first groups comprises m weights, and wherein m is an integer number; and
the second memory array is configured to store the plurality of indices in a plurality of second groups associated with the plurality of first groups based on a one-to-one mapping relationship, wherein each second group of the plurality of second groups comprises n indices representing addresses of n weights in a first group of the plurality of first groups and selected by the multiplexer circuit, and wherein n is an integer number less than m.

15. The integrated circuit of claim 14, wherein the n weights in the first group have n values, wherein other m−n weights in the first group have m−n values, and wherein each of the n values is greater than each of the m−n values.

16. A method, comprising:
storing a plurality of weights in a first memory array of a memory device;
storing a plurality of indices in a second memory array of the memory device, wherein the plurality of indices are associated with a subset of the plurality of weights;
providing the subset of the plurality of weights to a multiplier circuit of the memory device;
providing a plurality of data to a multiplexer circuit of the memory device;
providing, to the multiplier circuit, a subset of the plurality of data selected by the multiplexer circuit based on the plurality of indices;
performing, using the multiplier circuit, multiplication operations on the subset of the plurality of data and the subset of the plurality of weights to calculate a plurality of products; and
performing, using an adder circuit of the memory device, an addition operation to calculate a sum of the plurality of products.

17. The method of claim 16, wherein:
storing the plurality of weights comprises dividing the plurality of weights into a plurality of first groups, wherein each first group of the plurality of first groups comprises m weights, and wherein m is an integer;
storing the plurality of indices comprises dividing the plurality of indices into a plurality of second groups, wherein the plurality of second groups are associated with the plurality of first groups based on a first one-to-one mapping relationship, wherein each second group of the plurality of second groups comprises n indices, and wherein n is an integer less than m; and
providing the subset of the plurality of weights comprises dividing the subset of the plurality of weights into a plurality of third groups, wherein the plurality of third groups are associated with the plurality of first groups based on a second one-to-one mapping relationship, wherein each third group of the plurality of third groups comprises n weights, and wherein indices of a second group indicates addresses of weights of an associated third group in an associated first group.

18. The method of claim 17, wherein providing the plurality of data comprises dividing the plurality of data into a plurality of fourth groups, wherein the plurality of fourth groups are associated with the plurality of first groups based on a third one-to-one mapping relationship, and wherein each fourth group of the plurality of fourth groups comprises m data.

19. The method of claim 18, wherein providing the subset of the plurality of data comprises dividing the subset of the plurality of data into a plurality of fifth groups, wherein the plurality of fifth groups are associated with the plurality of fourth groups based on a fourth one-to-one mapping relationship, wherein each fifth group of the plurality of fifth groups comprises n data, and wherein the indices of the second group indicates addresses of data of an associated fifth group in an associated fourth group.

20. The method of claim 19, wherein performing the multiplication operations comprises performing the multiplication operations on the associated fifth group and the weights of the associated second group that share the same addresses.
